(19) United States
(12) Patent Application Publication
(10) Pub. No.: US 2025/0224358 A1
(43) Pub. Date: Jul. 10, 2025

(54) CRACK DETECTION METHOD FOR PIEZOELECTRIC ELEMENT AND CRACK DETECTION DEVICE FOR PIEZOELECTRIC ELEMENT

(71) Applicant: SUNCALL CORPORATION, Kyoto (JP)

(72) Inventor: Takashi Nakagawa, Kyoto (JP)

(21) Appl. No.: 19/090,567

(22) Filed: Mar. 26, 2025

Related U.S. Application Data
(63) Continuation of application No. PCT/JP2024/004961, filed on Feb. 14, 2024.

(30) Foreign Application Priority Data
Mar. 14, 2023 (JP) 2023039381

(51) Int. Cl. G01N 27/20; G01N 27/04

(52) U.S. Cl. CPC G01N 27/20; G01N 27/041

(57) ABSTRACT

A crack detection device and method for a piezoelectric element capable of reducing the possibility of erroneous detection has a voltage having a single or multiple resonant frequencies which is applied to a piezoelectric element using an impedance analyzer. A resistive component of an impedance between a pair of electrodes provided in the piezoelectric element alone due to the application of the voltage is measured by the impedance analyzer. A determination unit takes a peak value of the resistive component of the impedance at the resonance frequency having been measured into consideration and determines whether a crack has occurred in the piezoelectric element based on a preset threshold.

### FIELD OF THE INVENTION

The present invention relates to a crack detection method for a piezoelectric element and a crack detection device for a piezoelectric element.

### BACKGROUND OF THE INVENTION

In general electronic components using piezoelectric elements as actuators, particularly in HDD suspensions, the risk of cracks occurring in the piezoelectric elements has increased due to the recent demand for thickness reductions. However, the piezoelectric elements mounted on the HDD suspensions are small, and there is a problem that detection of the cracks by optical observation is difficult.

Therefore, in order to solve such a problem, a technique described in Japanese Patent No. 5489968 (Patent Literature 1) has been proposed.

The invention described in Patent Literature 1 involves applying a resonant-frequency voltage to a piezoelectric element, measuring the dielectric loss tangent between a pair of electrodes due to the application of the voltage, and detecting a crack in the piezoelectric element based on the magnitude of the peak of the dielectric loss tangent at the measured resonant frequency.

### SUMMARY OF THE INVENTION

The foregoing detection method measures the dielectric loss tangent, so that it has a problem that erroneous detection may occur. That is, as exemplified in FIG. 5, the dielectric loss tangent has the characteristic that it changes sharply around the resonant frequency. In FIG. 5, when the dielectric loss tangent is Tan D, the dielectric loss tangent (Tan D) changes sharply around the resonant frequency of 6.9 MHz.

To describe this point in detail, the dielectric loss tangent (Tan D) is expressed as Tan D=R/−X when the impedance Z is given as Z=R+jX. Therefore, at a frequency where the denominator X is close to zero, a slight difference in the X value greatly affects the dielectric loss tangent (Tan D). Thus, as shown in FIG. 5, the dielectric loss tangent (Tan D) changes sharply around the resonant frequency (6.9 MHz is exemplified in FIG. 5).

Accordingly, even a slight deviation in the measurement frequency can dramatically change the peak value to be obtained, making it very difficult to set the threshold value, and this causes a problem that erroneous detection may occur during implementation operation.

Accordingly, in view of the foregoing problem, an object of the present invention is to provide a crack detection method for a piezoelectric element and a crack detection device for a piezoelectric element that can reduce the possibility of erroneous detection.

The foregoing object of the present invention is achieved by the following means. Note that reference signs in an embodiment to be described later are added in parentheses, but the present invention is not limited thereto.

According to the first aspect of the present invention, a crack detection method for a piezoelectric element is characterized by including steps of applying a voltage having a single or multiple resonant frequencies to a piezoelectric element (22), measuring a resistive component of an impedance between a pair of electrodes (22a and 22b) of the piezoelectric element (22) alone due to an application of the voltage, and taking a peak value of the resistive component of the impedance having been measured into consideration and determining whether a crack has occurred in the piezoelectric element (22) based on a preset threshold value.

According to the second aspect of the present invention, a crack detection method for a piezoelectric element is characterized by including steps of applying a voltage having a single or multiple resonant frequencies and also applying an arbitrary DC voltage to the piezoelectric element (22), measuring a resistive component of an impedance between a pair of electrodes (22a, 22b) of the piezoelectric element (22) alone due to the application of the voltage, and taking a peak value of the resistive component of the impedance having been measured into consideration and determining whether a crack has occurred in the piezoelectric element (22) based on a preset threshold value.

According to the third aspect of the present invention, the crack detection method for the piezoelectric element according to the above first and second aspects is characterized in that, when determining whether a crack has occurred in the piezoelectric element (22) based on the preset threshold value, a plurality of the peak values of the resistive component of the impedance having been measured are used and all of these determination results are taken into consideration to determine whether a crack has occurred in the piezoelectric element (22).

According to the fourth aspect of the present invention, a crack detection device for a piezoelectric element is characterized by including a voltage application means (impedance analyzer 3) for applying a voltage having a single or multiple resonant frequencies to a piezoelectric element (22), a measurement means (impedance analyzer 3) for measuring a resistive component of an impedance between a pair of electrodes (22a and 22b) of the piezoelectric element (22) alone due to the application of the voltage, and a determination means (determination unit 43a) for taking a peak value of the resistive component of the impedance having been measured at the resonant frequency into consideration and determining whether a crack has occurred in the piezoelectric element (22) based on a preset threshold value.

According to the fifth aspect of the present invention, a crack detection device for a piezoelectric element is characterized by including a voltage application means (impedance analyzer 3) for applying a voltage having a single or multiple resonant frequencies and also applying an arbitrary DC voltage to a piezoelectric element (22), a measurement means (impedance analyzer 3) for measuring a resistive component of an impedance between a pair of electrodes (22a and 22b) of the piezoelectric element (22) alone due to the application of the voltage, and a determination means (determination unit 43a) for taking a peak value of the resistive component of the impedance having been measured into consideration and determining whether a crack has occurred in the piezoelectric element (22) based on the preset threshold value.

Next, advantageous effects of the present invention will be described with reference signs of the drawings. Note that reference signs in an embodiment to be described later are added in parentheses, but the present invention is not limited thereto.

According to embodiments of the invention, the resistive component of the impedance between the pair of electrodes (22a, 22b) of the piezoelectric element (22) alone due to the application of a voltage is measured, the peak value of the resistive component of the impedance having been measured is taken into consideration, and it is determined whether a crack has occurred in the piezoelectric element (22) based on a preset threshold value. Thereby the possibility of erroneous detection can be reduced.

According to embodiments of the invention, in addition to the advantageous effects of other embodiments, an arbitrary DC voltage is further applied, thereby making it easier to set a threshold value, and the possibility of erroneous detection can be further reduced.

According to embodiments of the invention, the possibility of erroneous detection can be further reduced.

### BRIEF DESCRIPTION OF THE DRAWINGS

FIG. 1 is a schematic configuration diagram showing a crack detection device for a piezoelectric element according to an embodiment of the present invention.

FIG. 2 is a waveform diagram where a resistive component of an impedance between a pair of electrodes at a resonant frequency of the piezoelectric element according to the same embodiment is measured.

FIG. 3 is a waveform diagram different from that of FIG. 2.

FIG. 4 (a) is a waveform diagram in which a portion surrounded by a square frame A shown in FIG. 3 is enlarged, and FIG. 4 (b) is a waveform diagram in which a portion surrounded by a square frame B shown in FIG. 3 is enlarged.

FIG. 5 is a waveform diagram where a dielectric loss tangent between pairs of electrodes at a resonant frequency of piezoelectric elements according to the same embodiment are measured.

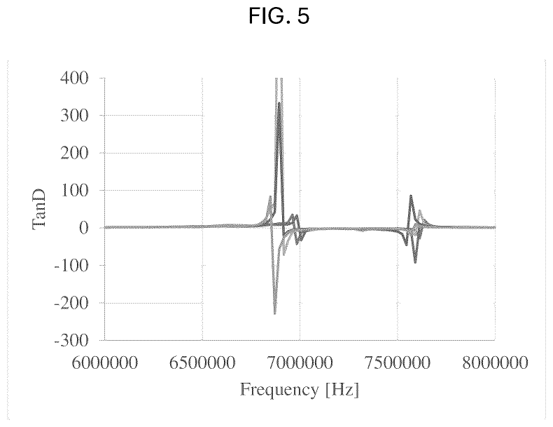

### DESCRIPTION OF THE PREFERRED EMBODIMENTS

Hereinafter, a crack detection device for a piezoelectric element according to an embodiment of the present invention will be specifically described with reference to the drawings. Note that in the following description, when directions up, down, left, and right are indicated, it shall mean up, down, left, and right when viewed from the front of the figure.

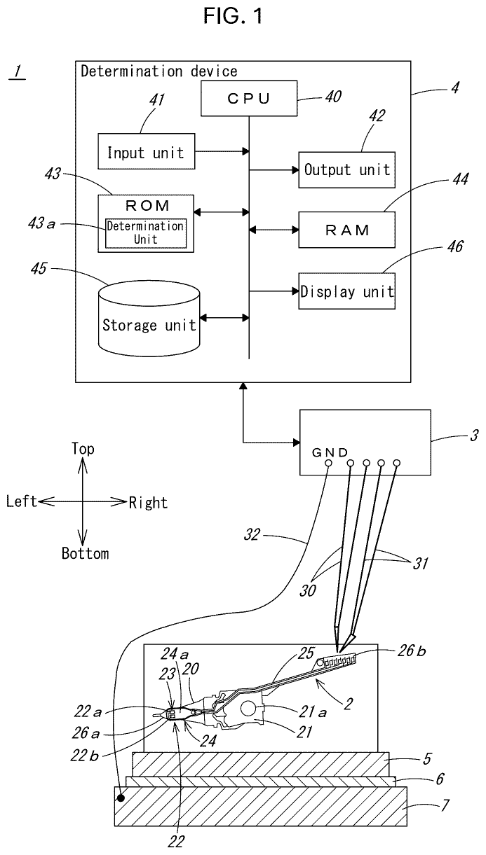

A crack detection device 1 for a piezoelectric element shown in FIG. 1 can detect a crack in the piezoelectric element by measuring the resistive component of an impedance between a pair of electrodes provided in the piezoelectric element alone. To describe this point more specifically, the crack detection device 1 for the piezoelectric element shown in FIG. 1 is mainly composed of an HDD suspension 2, which is an object to be measured, an impedance analyzer 3, and a determination device 4. Hereinafter, each component will be described in detail.

The HDD suspension 2 has a configuration similar to that of the conventional one, and as shown in FIG. 1, mainly includes a load beam 20 as a driven member, a base plate 21 as a base portion, and a piezoelectric element 22. The load beam 20 applies a load onto a head portion 23 on a distal end side (left side in the figure) shown in FIG. 1, and is made of, for example, a thin metal plate such as stainless steel having a spring property. As shown in FIG. 1, a flexure 24 as a wiring member is attached to the load beam 20.

As shown in FIG. 1, the flexure 24 is formed by forming a wiring pattern 25 on a conductive thin plate 24a such as a thin rolled stainless steel plate having a spring property via an electrical insulating layer. The wiring pattern 25 is composed of a wiring portion for signal transmission and a wiring portion for power supply. The wiring pattern 25 has both ends provided with terminal portions 26a and 26b as shown in FIG. 1.

On the other hand, as shown in FIG. 1, the flexure 24 has a distal end side (left side in the figure) provided with the head portion 23 supporting the piezoelectric element 22. This piezoelectric element 22 is conductively connected to the terminal portion 26a on one end side (left side in the figure) of the wiring pattern 25.

On the other hand, as shown in FIG. 1, the load beam 20 has a proximal end side (right side in the figure) supported by the base plate 21. As shown in FIG. 1, the base plate 21 is provided with a substantially circular boss portion 21a. The base plate 21 is attached to a carriage side (not shown) via the boss portion 21a and is rotationally driven by a voice coil motor.

The piezoelectric element 22 is made of piezoelectric ceramics such as lead zirconate titanate (PZT) and includes a pair of electrodes 22a and 22b as shown in FIG. 1. In the present embodiment, the presence or absence of a crack in the piezoelectric element 22 is detected by measuring the resistive component of an impedance between the pair of electrodes 22a and 22b of the single piezoelectric element 22.

Thus, the HDD suspension 2, which is an object to be measured, configured as described above is placed on a measurement table 5 having a horizontally long rectangular shape in cross section as shown in FIG. 1 for measurement. As shown in FIG. 1, an insulating material 6 having a horizontally long rectangular shape in cross section is provided on the under surface of the measurement table 5, and a base 7 of equipment having a horizontally long rectangular shape in cross section is provided on the under surface of the insulating material 6.

The impedance analyzer 3 can measure the resistive component of the impedance between the pair of electrodes 22a and 22b of the single piezoelectric element 22 described above. Specifically, as shown in FIG. 1, the impedance analyzer 3 has a measurement signal output side connected with two first measurement cables 30 and a measurement signal reception side connected with two second measurement cables 31. The first measurement cables 30 and the second measurement cables 31 are connected to the terminal portion 26b on the other end side (right side in the figure) of the wiring pattern 25 described above. As a result, a measurement voltage at a frequency according to the setting can be applied from the impedance analyzer 3 to the HDD suspension 2, which is an object to be measured, via the first measurement cables 30. In this way, a voltage having a single or multiple resonant frequencies can be applied to the piezoelectric element 22 described above by the impedance analyzer 3.

Meanwhile, when the voltage having a single or multiple resonant frequencies is applied to the piezoelectric element 22 as described above, the impedance analyzer 3 can receive and measure the resistive component of the impedance between the pair of electrodes 22a and 22b at the resonant frequency of the piezoelectric element 22 via the second measurement cables 31. The measured value of the resistive component of the impedance is then output to the determination device 4 shown in FIG. 1. As shown in FIG. 1, the impedance analyzer 3 is connected with a ground cable 32, and the ground cable 32 is connected to the base 7.

The determination device 4 is composed of a personal computer (PC) or the like, and as shown in FIG. 1, is composed of a CPU 40, an input unit 41 capable of inputting predetermined data to the determination device 4, an output unit 42 capable of outputting predetermined data outside the determination device 4, a ROM 43 composed of a writable flash ROM, etc., storing a predetermined application program or the like, a RAM 44 functioning as a work area, a buffer memory, or the like, a storage unit 45 composed of a hard disk, etc., and a display unit 46 composed of a liquid crystal display (LCD), etc.

Thus, since the predetermined application program is stored in the ROM 43, the determination device 4 thus configured is provided with a determination unit 43a as functional blocks. The determination unit 43a determines whether a crack has occurred in the piezoelectric element 22 depending on whether the measured value of the resistive component of the impedance measured by the impedance analyzer 3 is equal to or greater than the threshold value stored in advance in the storage unit 45. This point will be described in detail by describing a usage example of the crack detection device 1 for the piezoelectric element.

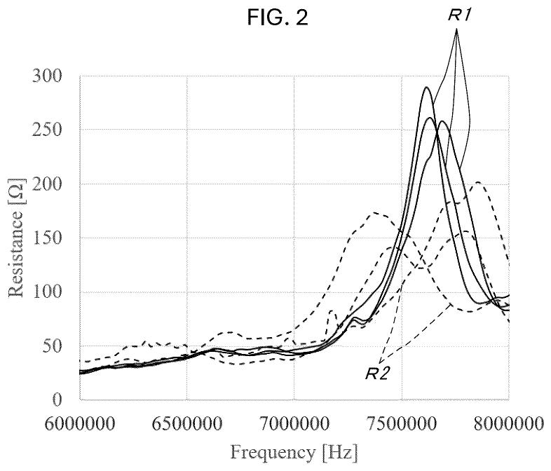

Thus, the crack detection device 1 for the piezoelectric element configured as described above first sets a threshold value. Specifically, for a plurality of HDD suspensions 2, the impedance analyzers 3 are used to apply the voltage having a single or multiple resonant frequencies to the piezoelectric elements 22 and receive and measure the resistive components of the impedances between the pairs of electrodes 22a and 22b at the resonant frequency of the piezoelectric elements 22, as described above. This makes it possible to obtain the waveform as shown in FIG. 2. Specifically, there is a clear difference between a waveform R1 group in which the resistive component of the impedance reaches its peak value (around 250Ω in the figure) around the resonant frequency of 7.6 MHz and a waveform R2 group in which it does not.

The waveform R1 group in which the resistive component of the impedance reaches its peak value (around 250Ω in the figure) around the resonant frequency of 7.6 MHz indicates that the piezoelectric element 22 is a good product (no cracks have occurred). Since there is a clear difference, the threshold value of the resistive component of the impedance around the resonant frequency of 7.6 MHz can be set to, for example, 160Ω.

When the threshold value is input using the input unit 41 of the determination device 4 shown in FIG. 1, the threshold value is stored in the storage unit 45 by the CPU 40.

Thus, if the threshold value is set in this manner, the determination unit 43a determines whether the determination value of the resistive component of the impedance measured by the impedance analyzer 3 is equal to or greater than the threshold value (160Ω in this embodiment) stored in advance in the storage unit 45. If the determination value is equal to or greater than the threshold value, it is determined that no crack has occurred in the piezoelectric element 22, if the determination value is not equal to or greater than the threshold value, it is determined that a crack has occurred in the piezoelectric element 22. This makes it possible to detect a crack in the piezoelectric element without optical observation in the same manner as in the conventional art.

Furthermore, as described above, in the present embodiment, the presence or absence of a crack in the piezoelectric element 22 is detected by measuring the resistive component of the impedance between the pair of electrodes 22a and 22b. Thereby since the peak value of the resistive component of the impedance at the resonant frequency is clearly different as shown in FIG. 2, this makes it easy to set the threshold value, so that the possibility of erroneous detection can be reduced during implementation operation.

Thus, according to the present embodiment the possibility of erroneous detection can be reduced.

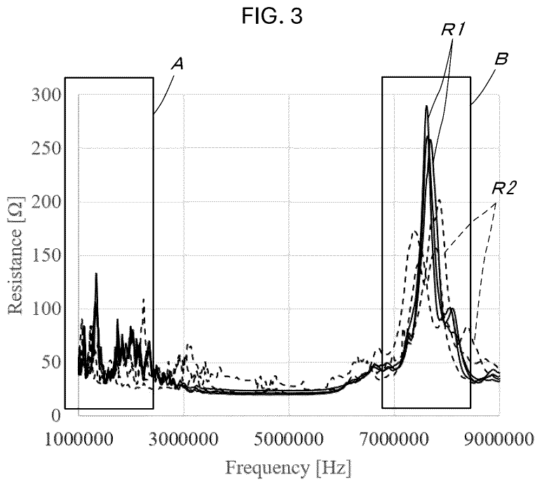

Meanwhile, depending on how the cracks in the piezoelectric element 22 are made, a waveform like FIG. 3 may be shown, which is different from FIG. 2.

That is, as shown in FIG. 3, there is a waveform R2 group in which the peak value of the resistive component of the impedance around the resonant frequency of 7.6 MHz is around 160 Ω of the threshold value set above. Therefore, in this state even if a crack occurs in the piezoelectric element 22, it may be determined that no crack has occurred, resulting in erroneous detection.

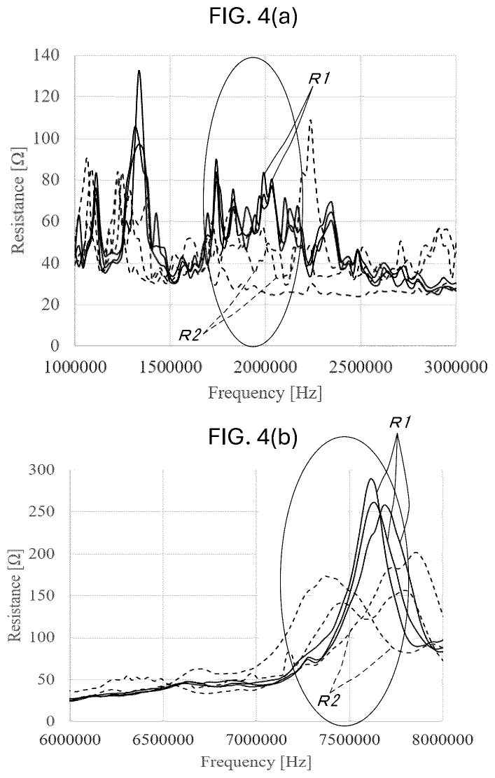

Therefore in the present embodiment, in order to further reduce the possibility of erroneous detection, multiple threshold values are set, so that it is determined that no crack has occurred in the piezoelectric element 22 if the determination value for the measured value of the resistive component of the impedance is equal to or greater than all the threshold values set. This point is specifically explained below. An enlarged portion surrounded by a square frame A in FIG. 3 is shown in FIG. 4(a). Here, there is a clear difference between a waveform R1 group in which the resistive component of the impedance reaches its peak value (around 75Ω in the figure) around the resonant frequency of 2.0 MHz and a waveform R2 group in which it does not. Therefore, the threshold value of the resistive component of the impedance around the resonant frequency of 2.0 MHz can be set as, for example, 65Ω. When this threshold value is input using the unit 41 of the determination device 4 shown in FIG. 1, it is stored in the storage unit 45 by the CPU 40.

Meanwhile, an enlarged portion surrounded by a square frame B in FIG. 3 is shown in FIG. 4(b). Here, there is a clear difference between a waveform R1 group in which the resistive component of the impedance reaches its peak value (around 250Ω in the figure) around the resonant frequency of 7.6 MHz and a waveform R2 group in which it does not. Therefore, the threshold value of the resistive component of the impedance at the resonant frequency of 7.6 MHz can be set as, for example, 200Ω. When this threshold value is input using the input unit 41 of the determination device 4 shown in FIG. 1, it is stored in the storage unit 45 by the CPU 40.

Thus, the determination unit 43a determines that no cracks have occurred in the piezoelectric elements 22 depending on whether the measured value of the resistive component of the impedance measured by the impedance analyzer 3 is equal to or greater than the threshold value (65Ω) around the resonant frequency of 2.0 MHz and also is equal to or greater than the threshold value (200Ω) around the resonant frequency of 7.6 MHz. On the other hand, if neither of these conditions is met, the determination unit 43a determines that a crack has occurred in the piezoelectric element 22. Thus the possibility of erroneous detection can be further reduced even if there is a difference in the waveforms that are generated depending on how the cracks in the piezoelectric element 22 are made.

Note that the shapes and the like shown in the present embodiment are merely examples, and various modifications and changes can be made within the scope of the gist of the present invention described in the claims.

For example, in the present embodiment, an example has been shown in which the impedance analyzer 3 applies a voltage having a single or multiple resonant frequencies to the piezoelectric element 22, but the present invention is not limited to this. The impedance analyzer 3 may apply a voltage having a single or multiple resonant frequencies and also apply an arbitrary DC voltage to the piezoelectric element 22. In this way, by applying the arbitrary DC voltage to the piezoelectric element 22, the applied voltage becomes higher than when only applying a voltage having a single or multiple resonant frequencies, and the peak value of the resistive component of the impedance becomes sharper. Therefore, it becomes easier to set a threshold value. Then, the possibility of erroneous detection can be further reduced.

Further, the HDD suspension 2 has been described as an example in the present embodiment, but the present invention is not limited thereto and can be applied to any type of piezoelectric element.

Further, in the present embodiment, an example is shown in which it is determined that no cracks have occurred in the piezoelectric element 22 if the measured value of the resistive component of the impedance is equal to or greater than the two threshold values shown in FIG. 3 and FIG. 4, but the present invention is not limited to this and of course it may be determined based on whether the measured value of the resistive component of the impedance is equal to or greater than three or more threshold values.

In the present embodiment, an example is shown in which it is determined whether a crack has occurred in the piezoelectric element 22 depending on whether the measured value of the resistive component of the impedance measured by the impedance analyzer 3 is equal to or greater than the threshold value previously stored in the storage unit 45. However, the present invention is not limited to this and it may be determined whether a crack has occurred in the piezoelectric element 22 depending on whether the measured value of the resistive component of the impedance measured by the impedance analyzer 3 is equal to or less than the threshold value previously stored in the storage unit 45.

What is claimed:

1. A crack detection method for a piezoelectric element, comprising the steps of:
applying a voltage having a single or multiple resonant frequencies to a piezoelectric element;
measuring a resistive component of an impedance between a pair of electrodes of the piezoelectric element alone due to the application of the voltage; and
taking a peak value of the resistive component of the impedance having been measured into consideration and determining whether a crack has occurred in the piezoelectric element based on a preset threshold value.

2. A crack detection method for a piezoelectric element, comprising the steps of:
applying a voltage having a single or multiple resonant frequencies and also applying an arbitrary DC voltage to a piezoelectric element;
measuring a resistive component of an impedance between a pair of electrodes of the piezoelectric element alone due to the application of the voltage; and
taking a peak value of the resistive component of the impedance having been measured into consideration and determining whether a crack has occurred in the piezoelectric element based on a preset threshold value.

3. The crack detection method for the piezoelectric element according to claim 1, wherein when determining whether a crack has occurred in the piezoelectric element based on the preset threshold value, the method further comprises using a plurality of the peak values of the resistive component of the impedance having been measured, and all of these determination results are taken into consideration to determine whether a crack has occurred in the piezoelectric element.

4. The crack detection method for the piezoelectric element according to claim 2, wherein when determining whether a crack has occurred in the piezoelectric element based on the preset threshold value, the method further comprises using a plurality of the peak values of the resistive component of the impedance having been measured, and all of these determination results are taken into consideration to determine whether a crack has occurred in the piezoelectric element.

5. A crack detection device for a piezoelectric element, comprising:
a voltage application means operable to apply a voltage having a single or multiple resonant frequencies to a piezoelectric element;
a measurement means operable to measure a resistive component of an impedance between a pair of electrodes of the piezoelectric element alone due to the application of the voltage; and
a determination means operable to take a peak value of the resistive component of the impedance having been measured into consideration and operable to determine whether a crack has occurred in the piezoelectric element based on a preset threshold value.

6. A crack detection device for a piezoelectric element, comprising:
a voltage application means operable to apply a voltage having a single or multiple resonant frequencies and also applies an arbitrary DC voltage to a piezoelectric element;
a measurement means operable to measure a resistive component of an impedance between a pair of electrodes of the piezoelectric element alone due to the application of the voltage; and
a determination means operable to take a peak value of the resistive component of the impedance having been measured into consideration and operable to determine whether a crack has occurred in the piezoelectric element based on a preset threshold value.
